(19) United States
(12) Patent Application Publication
(10) Pub. No.: US 2019/0006586 A1
(43) Pub. Date: Jan. 3, 2019

(54) CHALCOGENIDE FILMS FOR SELECTOR DEVICES

(71) Applicant: ASM IP HOLDING B.V., Almere (NL)

(72) Inventors: Jan Willem Maes, Wilrijk (BE); Suvi Haukka, Helsinki (FI)

(21) Appl. No.: 16/021,393

(22) Filed: Jun. 28, 2018

Related U.S. Application Data
(60) Provisional application No. 62/526,494, filed on Jun. 29, 2017.

(51) Int. Cl. H01L 45/00; C23C 16/455; C23C 16/30; H01L 21/02

(52) U.S. Cl. CPC H01L 45/1616; C23C 16/45553; C23C 16/305; H01L 21/0262; H01L 21/02568; H01L 21/0257; H01L 45/143

(57) ABSTRACT

Methods are provided for depositing doped chalcogenide films. In some embodiments the films are deposited by vapor deposition, such as by atomic layer deposition (ALD). In some embodiments a doped GeSe film is formed. The chalcogenide film may be doped with carbon, nitrogen, sulfur, silicon, or a metal such as Ti, Sn, Ta, W, Mo, Al, Zn, In, Ga, Bi, Sb, As, V or B. In some embodiments the doped chalcogenide film may be used as the phase-change material in a selector device.

### CROSS-REFERENCE TO RELATED APPLICATION

This application claims priority to U.S. Provisional Application No. 62/526,494, filed Jun. 29, 2017, which is hereby incorporated by reference in its entirety.

### FIELD OF THE INVENTION

The present application relates generally to methods and compounds for forming chalcogenide films, such as for selector devices.

### BACKGROUND

Chalcogenide phase change materials can show a large change of resistivity when transitioning from the amorphous phase to a crystalline phase or from a crystalline phase to an amorphous phase. Such phase changes (both directions) can be induced by temperature change, such as by heating the material via a current sent through the material. Depending on how the heating and cooling is done, the phase change may immediately revert back again upon cooling down, or may not revert back again upon cooling down and stay in place. When the phase change material does not revert back to its original state upon cooling, the material can be used to make a non-volatile memory device. When the phase change is immediately reversible upon cooling down, the material can be used as a selector device for memory devices, having high resistance at low current, and low resistance at high current, i.e. a diode like operation. Performance parameters of such a device may include the temperature and current or current density at which the switching takes place, the resistivity obtained in both states and the speed at which the switching takes place.

Existing phase change materials such as GeSbTe are not suitable for selector devices, as they do not show the required reversible switching behavior.

### SUMMARY OF THE INVENTION

In some aspects, methods of depositing doped chalcogenide films are provided. The doped chalcogenide films may be phase change materials. In some embodiments the doped chalcogenide films may be used in selector devices.

In some embodiments, cyclic vapor deposition processes are used to form the doped chalcogenide films. In some embodiments atomic layer deposition (ALD) methods are used. The ALD methods for forming a doped chalcogenide film on a substrate may comprise multiple deposition cycles in which the substrate is alternately and sequentially contacted with two or more reactants for forming the chalcogenide material. The substrate is contacted with a third dopant precursor in one or more of the deposition cycles. In some embodiments the substrate is alternately and sequentially contacted with each of the reactants in every deposition cycle. In some embodiments the substrate is contacted with the dopant precursor at intervals in the deposition process.

In some embodiments the ALD process comprises a first primary deposition cycle in which the substrate is alternately and sequentially contacted with the first reactant and second reactant for form a chalcogenide material and a second dopant sub-cycle in which the substrate is contacted with the dopant precursor. In some embodiments the substrate is alternately and sequentially contacted with the dopant precursor and one of the first and second reactants in the dopant sub-cycle. The dopant sub-cycle may be provided at a desired ratio to the primary deposition cycle in the deposition process.

In some embodiments the first reactant in the chalcogenide deposition is an alkyl silyl precursor and the second reactant is a metal halide precursor. In some embodiments the dopant precursor comprises a halide or alkyl silyl compound.

In some embodiments the doped chalcogenide film comprises one or more of GeSe, SbTe, GeTe, GeSbTe, BiTe, ZnSe and ZnTe. In some embodiments the film is doped with one or more dopants selected from C, Sb, As, Si, S, N, Ti, Sn, Ta, W, Mo, Al, Zn, In, Ga, Bi, Sb, As, V and B.

In some embodiments the doped chalcogenide film is a doped GeSe film. In some embodiments the first reactant is a germanium halide and the second reactant is an alkyl silyl selenium compound. The first reactant may comprise GeCl₂—C₄H₈O₂ and the second reactant may comprise (Et₃Si)Se₂. The dopant precursor may comprise one or more dopants selected from C, Sb, As, Si, S, N, Ti, Sn, Ta, W, Mo, Al, Zn, In, Ga, Bi, Sb, As, V and B.

In some embodiments a process for depositing a doped chalcogenide film on a substrate comprises a plurality of complete deposition cycles, each complete deposition cycle comprising a chalcogenide deposition sub-cycle and a dopant sub-cycle. The chalcogenide deposition sub-cycle may comprise alternately and sequentially contacting the substrate with a metal precursor and a chalcogenide precursor. The dopant sub-cycle may comprise contacting the substrate with a first dopant precursor. In some embodiments the dopant sub-cycle comprises alternately and sequentially contacting the substrate with the first dopant precursor and a second reactant. The second reactant may comprise the same chalcogenide precursor as in the chalcogenide deposition sub-cycle. In some embodiments the chalcogenide deposition sub-cycle and dopant sub-cycle are both ALD processes.

### BRIEF DESCRIPTION OF THE DRAWINGS

The invention will be better understood from the Detailed Description and from the appended drawings, which are meant to illustrate and not to limit the invention, and wherein:

FIG. 1 illustrates a deposition process flow for depositing a doped chalcogenide thin film by an atomic layer deposition process.

### DESCRIPTION

Doped chalcogenide films, such as doped GeSe films, have a relatively high crystallization temperature and may act as phase change materials. In some embodiments the doped chalcogenide films have characteristics that make them suitable for use as selector devices. In some embodiments the doped chalcogenide films can be induced to undergo a phase change, such as from amorphous to crystalline, by temperature change, such as by heating the material via a current sent through the material. In some embodiments the phase change may be reversed by cooling. In some embodiments the resistance of a doped chalcogenide film can be adjusted by adjusting the temperature. For example, by increasing or decreasing a current through the material the resistance of the material may be adjusted.

The dopant in the doped chalcogenide films can increase the crystallization temperature relative to the corresponding un-doped chalcogenide films, and in some embodiments may do so without significantly deteriorating the reversible switching characteristic of the films and/or the resistivity of the films in both the crystalline and amorphous states. Dopants in the chalcogenide films may include, for example, one or more of C, Sb, As, Si, S, N, Ti, Sn, Ta, W, Mo, Al, Zn, In, Ga, Bi, Sb, As, V and B. In some embodiments, a doped chalcogenide film can serve a as a selector device, for example for memory circuits.

While various embodiments are discussed in the general context of the formation of doped chalcogenide films that can serve as selector films, the skilled artisan will appreciate that the principles and advantages taught herein will have application to other devices and applications. Furthermore, while a number of processes are disclosed herein, one of ordinary skill in the art will recognize the utility of certain of the disclosed steps in the processes, even in the absence of some of the other disclosed steps, and similarly that subsequent, prior and intervening steps can be added.

In some embodiments, doped chalcogenide films are deposited by a vapor deposition process. In some embodiments a doped chalcogenide thin film is deposited on a substrate in a reaction space by a cyclical vapor deposition process. The cyclical deposition process is typically surface-controlled (based on controlled reactions at the substrate surface) and thus has the advantage of providing high conformality. However, in some embodiments, one or more of the reactants may at least partially decompose. Accordingly, in some embodiments the cyclical processes described herein are pure ALD process in which no decomposition of precursors is observed. In other embodiments, reaction conditions, such as reaction temperature, are selected such that at least some decomposition takes place.

Cyclical deposition processes are based on alternatingly providing vapor phase reactants to a reaction space to interact with a substrate surface contained therein. Gas phase reactions are avoided by feeding the precursors alternately and sequentially into the reaction chamber. Vapor phase reactants may be separated from each other in the reaction chamber, for example, by removing excess reactants and/or reactant by-products from the reaction chamber between reactant pulses. Removal may occur through the use of a purge gas and/or an applied vacuum.

In some embodiments a vapor deposition process comprises at least one deposition cycle in which a substrate is alternately and sequentially contacted with a first reactant and a second chalcogenide reactant to form a chalcogenide material on the substrate surface. The substrate is also contacted with a dopant precursor to provide the dopant to the growing chalcogenide film. In some embodiments the dopant precursor may be alternately and sequentially provided with the first and second reactants. In some embodiments the dopant precursor may be provided in a distinct deposition cycle (or sub-cycle), either individually or in combination with one or more additional reactants.

As mentioned above, in some embodiments doped chalcogenide films can be deposited by atomic layer deposition (ALD) processes. ALD-type processes are based on controlled, generally self-limiting surface reactions of precursor chemicals. Gas phase reactions are typically avoided by feeding the precursors alternately and sequentially into the reaction chamber. Vapor phase reactants are separated from each other in the reaction chamber, for example by removing excess reactants and/or reactant byproducts from the reaction chamber between reactant pulses.

Briefly, a substrate is loaded into a reaction chamber and is heated to a suitable deposition temperature, generally at lowered pressure. Deposition temperatures are typically maintained below the thermal decomposition temperature of the reactants but at a high enough level to avoid condensation of reactants and to provide the activation energy for the desired surface reactions. The temperature varies depending on the type of film being deposited and may be, for example, at or below about 500° C. at or below about 400° C., at or below about 200° C. or in some embodiments from about 20° C. to about 200° C.

A first reactant is conducted or pulsed into the chamber in the form of a vapor phase pulse and contacted with the surface of the substrate. Conditions are preferably selected such that no more than about one monolayer of species of the first reactant are adsorbed on the substrate surface in a self-limiting manner. However, depending on the particular reaction and desired process, in some embodiments more than one monolayer of reactant species may adsorb in each pulse. The appropriate pulsing times can be readily determined by the skilled artisan based on the particular circumstances. Excess first reactant and reaction byproducts, if any, are removed from the reaction chamber, such as by purging with an inert gas and/or evacuating the chamber.

Purging the reaction chamber means that excess vapor phase precursors and/or vapor phase byproducts are removed from the reaction chamber such as by evacuating the chamber with a vacuum pump and/or by replacing the gas inside the reactor with an inert gas such as argon or nitrogen. Typical purging times are from about 0.05 to 20 seconds, more preferably between about 1 and 10, and still more preferably between about 1 and 2 seconds. However, other purge times can be utilized if necessary, such as where highly conformal step coverage over extremely high aspect ratio structures or other structures with complex surface morphology is needed.

A second gaseous reactant is pulsed into the chamber where it reacts with the species of the first reactant bound to the surface to form a chalcogenide film. Excess second reactant and gaseous byproducts of the surface reaction, if any, are removed from the reaction chamber, preferably by purging with the aid of an inert gas and/or evacuation. Although referred to as the first and second reactant, the pulsing order may be varied such that in some embodiments the second reactant may be provided first, species of the second reactant adsorb on the substrate surface and the first reactant reacts with the adsorbed species to form a chalcogenide material.

The steps of pulsing and purging are repeated until a thin chalcogenide film of the desired thickness and composition has been formed on the substrate. For ALD-type processes, each cycle typically leaves no more than a molecular monolayer.

The alternate and sequential contacting of the substrate with the first and second reactants can be referred to as a primary chalcogenide deposition cycle or chalcogenide deposition sub-cycle.

The dopant is provided in the chalcogenide film by a dopant sub-cycle comprising contacting the substrate with a third dopant reactant (also referred to as the dopant precursor). The dopant precursor is pulsed into the chamber and contacted with the substrate surface. Excess third dopant reactant and reaction byproducts, if any, are removed from the reaction chamber, such as by purging with the aid of an inert gas and/or by evacuating the chamber.

Thus, in some embodiments a cyclical deposition process comprises a primary deposition cycle and a dopant deposition cycle, such that the substrate is alternately and sequentially contacted with a first reactant, a second chalcogenide reactant and a third dopant precursor. Again, the reactants may be provided in any order, and in some embodiments the dopant sub-cycle may come before the chalcogenide deposition sub-cycle.

In some embodiments the dopant sub-cycle comprises a cyclical process comprising alternately and sequentially contacting the substrate with the dopant precursor and another reactant. In some embodiments the additional reactant is the same as one of the first or second reactants from the primary chalcogenide deposition cycle. In some embodiments the dopant sub-cycle is an ALD process.

The dopant sub-cycle may be carried out before or after one or more of the primary chalcogenide deposition cycles.

The primary chalcogenide deposition cycle and dopant sub-cycle are repeated at a desired ratio to form a doped chalcogenide film having the desired composition. In some embodiments the chalcogenide deposition sub-cycle and dopant sub-cycle are repeated the same number of time. However, in other embodiments the chalcogenide deposition sub-cycle and the dopant sub-cycle are repeated at a particular ratio in order to deposit a doped chalcogenide film having the desired concentration.

Additional phases or sub-cycles comprising provision of a reactant and purging of the reaction space can be included to form more complicated materials.

The process for forming the doped chalcogenide film may begin with either the chalcogenide or dopant sub-cycles. Further, the particular order that the reactants are provided in each sub-cycle and the order of the sub-cycles and their ratio can be selected by the skilled artisan based on the particular circumstances.

In some embodiments, a cyclic deposition process comprises multiple cycles in which the two or more reactants for forming the chalcogenide film and the third dopant reactant are provided alternately and sequentially to the reaction space. That is, each complete cycle in the process may be essentially the same, comprising the same primary chalcogenide deposition sub-cycle and the same dopant sub-cycle.

In some embodiments, an ALD process comprises a primary ALD cycle in which the substrate is alternately and sequentially contacted with two or more reactants to form the chalcogenide material, and a separate sub-cycle in which the substrate is contacted with the third dopant reactant. The sub-cycle may be provided after every primary ALD cycle or at intervals in the ALD process to obtain the desired composition. In some embodiments, the dopant reactant may be the only reactant provided in the dopant sub-cycle. In some embodiments in the dopant sub-cycle the substrate is alternately and sequentially contacted with the dopant reactant and one or more additional reactants. For example, the substrate may be contacted with a first reactant containing Ge, a second reactant containing Se and a third dopant reactant.

As mentioned above, each pulse or phase of each cycle in the ALD processes is typically self-limiting. An excess of reactant precursors is supplied in each phase to saturate the susceptible substrate surfaces. Surface saturation ensures reactant occupation of all available reactive sites (subject, for example, to physical size or “steric hindrance” restraints) and thus ensures excellent step coverage. However, in some embodiments the reaction conditions may be adjusted such that self-limiting behavior is not achieved. For example, more than one monolayer of material may be deposited in one or more deposition cycles, or phases of deposition cycles. In other embodiments less than one monolayer of material may be deposited.

Removing excess reactants can include evacuating some of the contents of the reaction space and/or purging the reaction space with helium, nitrogen or another inert gas. In some embodiments purging can comprise turning off the flow of the reactive gas while continuing to flow an inert carrier gas to the reaction space. In some embodiments a substrate may be moved from a reaction space containing one reactant to a reactant space containing a different reactant.

The precursors employed in the vapor deposition processes may be solid, liquid or gaseous materials under standard conditions (room temperature and atmospheric pressure), provided that the precursors are in vapor phase before they are conducted into the reaction chamber and contacted with the substrate surface. “Pulsing” a vaporized precursor onto the substrate means that the precursor vapor is conducted into the chamber for a limited period of time. Typically, the pulsing time is from about 0.05 to 10 seconds. However, depending on the substrate type and its surface area, the pulsing time may be even higher than 10 seconds. Pulsing times can be on the order of minutes in some cases. The optimum pulsing time can be determined by the skilled artisan based on the particular circumstances.

The mass flow rate of the precursors can also be determined by the skilled artisan. In some embodiments, the flow rate of metal precursors is preferably between about 1 and 1000 sccm without limitation, more preferably between about 100 and 500 sccm.

The pressure in the reaction chamber is typically from about 0.01 to about 20 mbar, more preferably from about 1 to about 10 mbar. However, in some cases the pressure will be higher or lower than this range, as can be determined by the skilled artisan given the particular circumstances.

Before starting the deposition of the film, the substrate is typically heated to a suitable growth temperature. The growth temperature varies depending on the type of thin film formed, the physical properties of the precursors, etc. The growth temperature can be less than the crystallization temperature for the deposited materials such that an amorphous thin film is formed or it can be above the crystallization temperature such that a crystalline thin film is formed. The preferred deposition temperature may vary depending on a number of factors such as, and without limitation, the reactant precursors, the pressure, flow rate, the arrangement of the reactor, crystallization temperature of the deposited thin film, and the composition of the substrate including the nature of the material to be deposited on. The specific growth temperature may be selected by the skilled artisan.

Examples of suitable reactors that may be used include commercially available ALD equipment such as the F-120® reactor, Pulsar® reactor and Advance® 400 Series reactor, available from ASM America, Inc of Phoenix, Ariz. and ASM Europe B.V., Almere, Netherlands. In addition to these ALD reactors, many other kinds of reactors capable of ALD growth of thin films, including CVD reactors equipped with appropriate equipment and means for pulsing the precursors can be employed.

The growth processes can optionally be carried out in a reactor or reaction space connected to a cluster tool. In a cluster tool, because each reaction space is dedicated to one type of process, the temperature of the reaction space in each module can be kept constant, which improves the throughput compared to a reactor in which is the substrate is heated up to the process temperature before each run.

A stand-alone reactor can be equipped with a load-lock. In that case, it is not necessary to cool down the reaction space between each run.

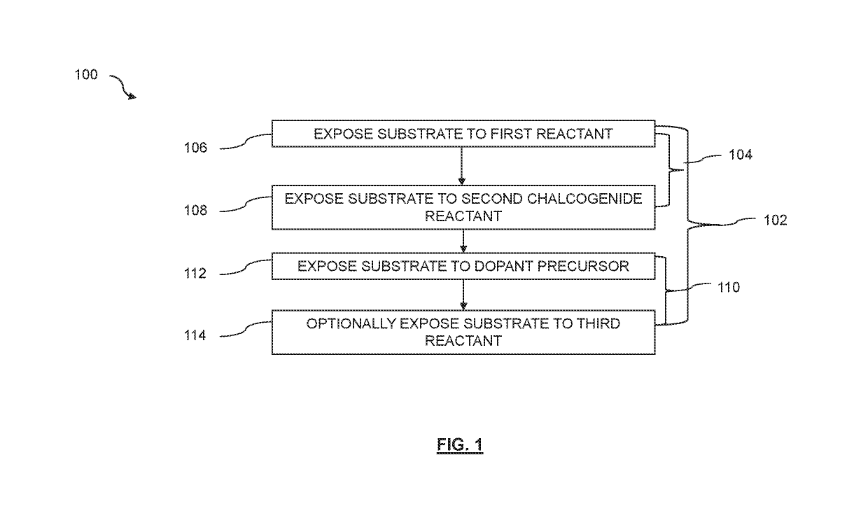

FIG. 1 shows a flow chart of an example of a process 100 for forming a doped chalcogenide film on a substrate. In some embodiments the process is a thermal ALD process. The process 100 can include a complete deposition cycle 102 having a primary chalcogenide deposition sub-cycle 104 and a dopant sub-cycle 110 for adding dopant to the growing chalcogenide film. In some embodiments, the chalcogenide deposition sub-cycle 104, dopant sub-cycle 110, and/or the complete deposition cycle 102 can be repeated a number of times to form a doped chalcogenide film having a desired composition and/or thickness. The ratio of the chalcogenide deposition sub-cycle 104 to the dopant sub-cycle 110 can be varied to tune the concentration of dopant in the film and thus to achieve a film with desired characteristics. For example, the number of times dopant sub-cycle 110 is repeated relative to the number of times the chalcogenide sub-cycle 104 is repeated can be selected to provide a doped chalcogenide film with desired characteristics (e.g., desired change in resistivity with change in temperature).

The chalcogenide deposition sub-cycle 104 can include blocks 106 and 108. In block 106, the substrate can be exposed to a first reactant, such as a metal reactant. In some embodiments the first reactant is a metal halide. In block 108, the substrate can be exposed to a second reactant, such as a chalcogenide reactant. In some embodiments the second reactant is an alkyl silyl chalcogenide. In some embodiments, chalcogenide sub-cycle 104 can be repeated a number of times (e.g., a number of repetitions of the blocks 106 and 108) prior to dopant sub-cycle 110. In some embodiments, block 106 or block 108 can be repeated a number of times before performing the other block one or more times. For example, block 106 can be repeated a number of times before performing block 108.

In some embodiments the chalcogenide material being deposited is GeSe. The first reactant in block 106 may be, for example, GeCl₂—C₄H₈O₂ and the second reactant in block 108 may be, for example, (Et₃Si)₂Se.

In some embodiments pulses of the first and second reactants are separated by a step of removing excess reactant from the reactor (not shown). In some embodiments excess second reactant is removed prior to repeating the chalcogenide deposition sub-cycle 104. In some embodiments, the chalcogenide deposition sub-cycle 104 is an ALD process. In some embodiments, the pulses of the first and second reactants may at least partially overlap. In some embodiments, no additional precursors are provided to the reaction chamber either between blocks 106 and 108, or before starting blocks 106 and 108.

The dopant sub-cycle 110 for introducing a dopant into the chalcogenide film can include blocks 112 and 114. In block 112, the substrate can be exposed to a precursor comprising the dopant of interest to be added to the film, such that species of the dopant precursor adsorb on the substrate surface. Exemplary dopant precursors are described below. In block 114, the substrate can optionally be exposed to a third reactant to react with the adsorbed first dopant reactant species. In some embodiments the third reactant is the same as one of the first or second reactants provided at blocks 106 and 108 of the chalcogenide deposition sub-cycle. For example, in some embodiments in which a doped GeSe film is formed, both the second and the third reactants may be may be, for example, (Et₃Si)₂Se.

In some embodiments, dopant sub-cycle 110 can be repeated a number of times. In some embodiments, block 112 or block 114 can be repeated a number of times before performing the other block. For example, block 112 can be repeated a number of times before performing block 114. In some embodiments block 114 is omitted and the substrate is only contacted with the dopant precursor in the dopant sub-cycle 110.

In some embodiments excess dopant precursor is removed prior to repeating the dopant sub-cycle 110. In some embodiments, excess dopant precursor from block 112 can be removed prior to exposing the substrate to the third reactant in block 114. In some embodiments, the dopant sub-cycle 110 is an ALD process. In some embodiments, the pulses of the dopant precursor and of the second reactant may at least partially overlap. In some embodiments, no additional precursors are provided to the reaction chamber either between blocks 112 and 114, or before starting blocks 112 and 114.

In some embodiments, a doped chalcogenide film formed according to process 100 described herein is a not a nanolaminate film. For example, distinct and separate layers within the deposited chalcogenide film are not visible, such that the doped chalcogenide film is a continuous or substantially continuous film.

The doped chalcogenide deposition process can also be written as S×[N×(Metal Reactant+Chalcogenide Reactant)+M×(Dopant Precursor+Third Reactant)], where S, N and M are independently selected integers, such that the entire doped chalcogenide deposition cycle is repeated S times, the chalcogenide deposition sub-cycle is repeated N times and the dopant sub-cycle is repeated M times. As discussed above, the third reactant is omitted in the dopant sub-cycle in some embodiments and in some embodiments the third reactant is the same as the chalcogenide reactant or the metal reactant.

### Doped Chalcogenide Films

As discussed above, doped chalcogenide films, such as doped GeSe films, can be deposited by vapor deposition processes, particularly cyclical vapor deposition processes such as ALD. A number of chalcogenide deposition sub-cycles are provided below.

In some embodiments, the doped chalcogenide films are deposited using alkyl silyl precursors in combination with metal halide precursors to form a chalcogenide film. A dopant is provided using a third precursor. A variety of chalcogenide films can be deposited, including GeSe, GeTe and GeSbTe.

A dopant reactant may be included in each ALD cycle in the disclosed processes, or may be provided at intervals in one or more dopant sub-cycles in the deposition process. In some embodiments, the substrate is contacted with a dopant precursor at one or more intervals during deposition of a chalcogenide film to form a doped chalcogenide film. The doped chalcogenide films may be used, for example, as selector devices.

In some embodiments, a doped GeSe film is deposited using a Ge halide precursor and a Se alkyl silyl precursor in an ALD process. A third dopant reactant is provided at one or more intervals to form a doped GeSe film. For example, GeSe can be deposited by an ALD process using GeCl2-C4H8O2 and (Et3Si)Se2 as the Ge and Se precursors. A dopant reactant may be provided in one or more dopant sub-cycles to form doped GeSe.

In some embodiments the dopant can be provided in the chalcogenide film using a halide precursor or an alkylsilyl precursor for the dopant.

In some embodiments, a dopant precursor is provided in every cycle of an ALD process for depositing a doped chalcogenide film. That is, an ALD process for depositing a doped chalcogenide film may comprise alternately and sequentially contacting a substrate with a first precursor, a second precursor, and a dopant precursor. For example, the dopant precursor may be provided alternately and sequentially with a Ge precursor and an Se precursor to produce a doped GeSe film.

In some embodiments, the chalcogenide material is deposited in a chalcogenide sub-cycle and a dopant is provided in one or more dopant sub-cycles. The dopant precursor is provided in one or more dopant sub-cycles that are provided at one or more points in an ALD process for forming the doped chalcogenide films. That is, a primary deposition cycle for forming the chalcogenide film may comprise alternately and sequentially contacting the substrate with a first precursor and second precursor, such as a Ge precursor and an Se precursor in a chalcogenide deposition suby-cycle. At one or more intervals in the deposition process a dopant sub-cycle is carried out in which the substrate is contacted with a dopant precursor. The substrate may be contacted with one or more additional precursors in the dopant sub-cycle. In some embodiments in the dopant sub-cycle the substrate is contacted with the dopant precursor and one or more additional reactants. For example, in some embodiments in the dopant sub-cycle the substrate is contacted with the dopant precursor and one of the recants from the primary ALD cycle. The ratio of chalcogenide deposition sub-cycles and dopant sub-cycles in the overall ALD process can be selected to achieve a desired level of dopant. In some embodiments dopant sub-cycles are provided at regular intervals during the deposition process.

In some embodiments more than one dopant is added to the chalcogenide film. For example, two or more different dopants may be added by using two or more different dopant sub-cycles in the deposition process.

In some embodiments a chalcogenide film is doped with one or more of C, B, S, and N.

In some embodiments a chalcogenide film is doped with one or more of As, Bi and Sb.

In some embodiments a chalcogenide film is doped with one or more of Ti, Ta, Mo, W and V.

In some embodiments a chalcogenide film is doped with one or more of Al, Zn, In and Ga.

In some embodiments a chalcogenide film is doped with one or more of Si and Sn.

In some embodiments a chalcogenide film is doped with carbon using a carbon dopant precursor. Exemplary carbon dopant precursors include CCl4 and similar Cl and C containing chemicals, such as chemicals with the formula CxHyClz where x, y and z are integers, e.g. CH3Cl or CH2Cl2.

In some embodiments a chalcogenide film is doped with a metal, such as Ti, Sn, Ta, W, Mo, Al, Zn, In, Ga, Bi, Sb, As, V or B.

In some embodiments a metal dopant is provided using a metal alkylsilyl compound as a dopant precursor.

In some embodiments a chalcogenide film is doped with As using an As dopant precursor. In some embodiments As doping can be done using an alkyl silyl As precursor, like (Et3Si)3As.

In some embodiments a chalcogenide film is doped with Sb using an Sb dopant precursor. In some embodiments Sb doping is done using an alkyl silyl precursor. In some embodiments Sb doing is done using (Me3Si)3Sb as the Sb dopant precursor.

In some embodiments the metal dopant is provided using a metal halide precursor. Exemplary metal halide precursors include, for example, TiCl4, SnCl4, GaCl3, TaCl5, WCl6, MoCl5, AlCl3, ZnClx, InClx, GeClx, BiClx, SbClx, AsClx, VClx, BCl3, and BBrx, where x is an integer.

A number of these dopant precursors have a fairly high vapor pressure (below 100° C.) and therefore may be utilized at the same deposition temperature as the chalcogenide deposition sub-cycle, typically at relatively low temp (50° C.-150° C.). For example the dopant sub-cycle can be carried out at the same temperature as the GeSe sub-cycle of a doped GeSe deposition process.

In some embodiments a chalcogenide film may be doped with nitrogen using a nitrogen dopant precursor. For example, nitrogen doping may be carried out using NH3 as a dopant reactant to provided nitrogen. In some embodiments NH3 is used in a deposition cycle with with GeClx and/or alkylsilyl selenium to form a nitrogen doped GeSe film.

In some embodiments a chalcogenide film may be doped with sulfur using a sulfur dopant precursor. In some embodiments an alkyl silyl sulfur compound is used as a sulfur dopant precursor.

In some embodiments, two Ge precursors might be used for forming a doped film, for example GeCl2X, where X is an organic ligand and GeCl4. The organic ligand of the Ge2X precursor can provide carbon doping in the film. In some embodiments a germanium alkylsilyl compound may be used as a Ge precursor.

In some embodiments alkoxide precursors (MO-R) can be used to provide dopants. For example, Si(OEt)4 (TEOS), or similar compounds can be used to provide metals such Ti, Ta, As etc.

In some embodiments metal chlorides, such as SbClx, and/or metal alkoxides, such as Sb(OEt)3 can be used in combination with one or more alkyl silyl precursors in a dopant sub-cycle.

In some embodiments BTBAS ((1,2-bis(diisopropylamino)disilane)) is used to provide Si as a dopant.

In some embodiments Ge analogs of BTBAS are used to dope a chalcogenide film with Ge.

In some embodiments carbon doping can be obtained as a byproduct of the use of an organic precursor.

In some embodiments, doped chalcogenide films are deposited by ALD preferably without the use of plasma. However in some cases plasma might be used in a plasma-enhanced ALD process (PEALD). For example, plasma may be used for doping of the films. In some embodiments a plasma reactant is used to dope the chalcogenide film, such as with O, N or Si. Is some embodiments a dopant sub-cycle comprises contacting a substrate with a plasma generated in a gas comprising O, N or Si, such that O, N or Si is added to the growing chalcogenide film as a dopant.

A number of exemplary chalcogenide deposition sub-cycles are provided below. In addition, in some embodiments the chalcogenide deposition sub-cycle may be essentially as described in U.S. Pat. No. 9,215,896 for forming chalcogenide films comprising Group VA elements (Sb, As, Bi, P) or in U.S. Pat. No. 9,175,390 for forming chalcogenide films comprising Se or Te, each of which is incorporated by reference herein.

In some embodiments a dopant sub-cycle is provided in combination with the chalcogenide deposition sub-cycles in each complete ALD cycle to form a doped chalcogenide film. In some embodiments in the dopant sub-cycle the dopant precursor and one of the reactants from the primary ALD cycle are alternately and sequentially provided. In some embodiments the dopant precursor is provided alternately and sequentially with a different reactant in the dopant sub-cycle. In some embodiments only the dopant precursor is provided in the dopant sub-cycle. In some embodiments the dopant sub-cycle is provided at one or more intervals in the ALD process to form a doped chalcogenide film.

In various embodiments any of the materials described below can be doped with desired dopants to form the doped chalcogenide films, such as for selector film applications. Dopants include those listed above, and may be, for example, N, O, Si, S, In, Ag, Sn, Au, As, Bi, Zn, Se, Te, Ge, Sb and Mn.

### Doped GeSe Deposition

In other embodiments a GeₓSe_{y}, preferably GeSe film can be formed essentially as described above, but using a Se precursor instead of a Te precursor. The Se precursor preferably has a formula of Se(SiR¹R²R³)₂, wherein R¹, R², and R³ are preferably alkyl groups with one or more carbon atoms. The skilled artisan can choose R¹, R², and R³ alkyl groups based on the desired physical properties of the precursor such as volatility, vapor pressure, toxicity, etc. In some embodiments the Se precursor is Se(SiMe₂^{t}Bu)₂. In other embodiments the Se precursor is Se(SiEt₃)₂. The ALD process conditions for forming a GeSe thin film, such as temperature, pulse/purge times, etc. can be selected by the skilled artisan based on routine experimentation and are essentially as described below for forming GeTe thin films.

The GeSe deposition sub-cycle can be combined with one or more dopant sub-cycles as described herein to form a doped GeSe film.

In some embodiments a Si doped GeSe film is deposited using a GeSe deposition sub-cycle comprising alternately and sequentially contacting the substrate with GeCl₂—C₄H₈O₂ and (Et₃Si)₂Se) and a dopant sub-cycle comprising alternately and sequentially contacting the substrate with SiCl₄ and (Et₃Si)₂Se. The sub-cycles and entire deposition cycle are repeated to form a doped GeSe film having the desired characteristics.

The deposition process can also be written as S×[N×(GeCl₂-C₄H₈O₂+(Et₃Si)₂Se))+M×(SiCl₄+(Et₃Si)₂Se)], where S, N and M are independently selected integers, such that the entire doped GeSe deposition cycle is repeated S times, the GeSe deposition sub-cycle is repeated N times and the dopant sub-cycle is repeated M times.

### Doped SbTe Deposition

According to some embodiments, an Sb₂Te₃ thin film is formed on a substrate in a reaction chamber by an ALD type process comprising multiple Sb—Te deposition cycles, each deposition cycle comprising:
providing a first vapor phase reactant pulse comprising a Te precursor into the reaction chamber to form no more than about a single molecular layer of the Te precursor on the substrate;
removing excess first reactant from the reaction chamber;
providing a second vapor phase reactant pulse comprising an Sb precursor to the reaction chamber such that the Sb precursor reacts with the Te precursor on the substrate to form Sb₂Te₃; and
removing excess second reactant and reaction byproducts, if any, from the reaction chamber.

This can be referred to as the Sb—Te deposition cycle. Each Sb—Te deposition cycle typically forms at most about one monolayer of Sb₂Te₃. The Sb—Te deposition cycle is repeated until a film of a desired thickness is formed. In some embodiments an Sb—Te film of from about 10 Å to about 2000 Å, preferably from about 50 Å to about 500 Å is formed.

Although the illustrated Sb—Te deposition cycle begins with provision of the Te precursor, in other embodiments the deposition cycle begins with the provision of the Sb precursor.

In some embodiments, the reactants and reaction by-products can be removed from the reaction chamber by stopping the flow of Te or Sb precursor while continuing the flow of an inert carrier gas such as nitrogen or argon.

Preferably, the Te precursor has a formula of Te(SiR¹R²R³)₂, wherein R¹, R², and R³ are alkyl groups comprising one or more carbon atoms. The R¹, R², and R³ alkyl groups can be selected on the desired physical properties of the precursor such as volatility, vapor pressure, toxicity, etc. In some embodiments the Te precursor is Te(SiMe₂^{t}Bu)₂. In other embodiments the precursor is Te(SiEt₃)₂ or Te(SiMe₃)₂.

In some embodiments the Sb source is SbX₃, wherein X is a halogen element. More preferably the Sb source is SbCl₃ or SbI₃.

In some embodiments the Te precursor is Te(SiEt₃)₂ and the Sb precursor is SbCl₃.

The substrate temperature during forming the Sb—Te thin film is preferably less than 250° C. and more preferably less than 200° C. and even more preferably below 100° C. If an amorphous thin film is desired the temperature can be lowered even further down to at or below about 90° C. In some embodiments the deposition temperature can be below about 80° C., below about 70° C., or even below about 60° C.

Pressure of the reactor can vary much depending from the reactor used for the depositions. Typically reactor pressures are below normal ambient pressure.

The skilled artisan can determine the optimal reactant evaporation temperatures based on the properties of the selected precursors. The evaporation temperatures for the Te precursor, such as Te(SiMe₂^{t}Bu)₂ and Te(SiEt₃)₂, which can be synthesized by the methods described herein, is typically about 40° C. to 45° C. Te(SiMe₃)₂ has a slightly higher vapor pressure than Te(SiMe₂^{t}Bu)₂ or Te(SiEt₃)₂ and thus Te(SiMe₃)₂ evaporation temperature is slightly lower from about 20 to 30° C. The evaporation temperature for the Sb precursor, such as SbCl₃, is typically about 30° C. to 35° C.

The skilled artisan can determine the optimal reactant pulse times through routine experimentation based on the properties of the selected precursors and the desired properties of the deposited SbTe thin film. Preferably the Te and Sb reactants are pulsed for about 0.05 to 10 seconds, more preferably about 0.2 to 4 seconds, and most preferably about 1 to 2 seconds. The purge steps in which excess reactant and reaction by-products, if any, are removed are preferably about 0.05 to 10 seconds, more preferably about 0.2-4 seconds, and most preferably 1 to 2 seconds in length.

The growth rate of the SbTe thin films will vary depending on the reaction conditions.

The SbTe deposition sub-cycle can be combined with one or more dopant sub-cycles as described herein to form a doped SbTe film.

### Doped SbSe Deposition

In other embodiments a SbₓSe_{y}, preferably Sb₂Se₃, film can be formed essentially as described above, by using a Se precursor instead of a Te precursor. The Se precursor preferably has a formula of 2 Se(SiR¹R²R³)₂, wherein R¹, R², and R³ are alkyl groups with one or more carbon atoms. The skilled artisan can choose R¹, R², and R³ alkyl groups based on the desired physical properties of the precursor such as volatility, vapor pressure, toxicity, etc. In some embodiments the Se precursor is Se(SiMe₂^{t}Bu)₂. In other embodiments the Se precursor is Se(SiEt₃)₂. The ALD process conditions for forming a SbSe thin film, such as temperature, pulse/purge times, etc. can be as described above for the deposition of SbTe films.

The SbSe deposition sub-cycle can be combined with one or more dopant sub-cycles as described herein to form a doped SbSe film.

### Doped GeTe Deposition

In other embodiments, a GeₓTe_{y}, preferably GeTe, thin film is formed by ALD without the use of plasma. In some embodiments a Ge—Te thin film is formed on a substrate by an ALD type process comprising multiple Ge—Te deposition cycles, each deposition cycle comprising:
providing a first vapor phase reactant pulse comprising a Te precursor into the reaction chamber to form no more than about a single molecular layer of the Te precursor on the substrate;
removing excess first reactant from the reaction chamber;
providing a second vapor phase reactant pulse comprising a Ge precursor to the reaction chamber such that the Ge precursor reacts with the Te precursor on the substrate; and
removing excess second reactant and reaction byproducts, if any, from the reaction chamber.

This can be referred to as the Ge—Te deposition cycle. Each Ge—Te deposition cycle typically forms at most about one monolayer of Ge—Te. The Ge—Te deposition cycle is repeated until a film of a desired thickness is formed. In some embodiments a Ge—Te film of from about 10 Å to about 2000 Å is formed.

Although the illustrated Ge—Te deposition cycle begins with provision of the Te precursor, in other embodiments the deposition cycle begins with the provision of the Ge precursor.

In some embodiments, the reactants and reaction by-products can be removed from the reaction chamber by stopping the flow of Te or Ge precursor while continuing the flow of an inert carrier gas such as nitrogen or argon.

The Te precursor may have a formula of 2 Te(SiR¹R²R³)₂, wherein R¹, R², and R³ are preferably alkyl groups with one or more carbon atoms. The skilled artisan can choose R¹, R², and R³ alkyl groups based on the desired physical properties of the precursor such as volatility, vapor pressure, toxicity, etc. In some embodiments the Te precursor is Te(SiMe₂^{t}Bu)₂. In other embodiments the Te precursor is Te(SiEt₃)₂ or Te(SiMe₃)2.

In some embodiments the Ge source is GeX₂ or GeX₄, wherein X is a halogen element. In some embodiments the Ge source is GeBr₂. In some embodiments the Ge source is germanium halide with coordinating ligands, such as dioxane ligands. Preferably the Ge source with coordinating ligands is germanium dihalide complex, more preferably a germanium dichloride dioxane complex GeCl₂—C₄H₈O₂.

The substrate temperature during deposition of the Ge—Te thin film is preferably less than about 300° C. and more preferably less than about 200° C. and even more preferably less than about 150° C. When GeBr₂ is used as the Ge precursor the process temperature is typically above about 130° C.

In some embodiments, however, the substrate temperature during deposition of the Ge—Te thin film is preferably less than 130° C. For example, when a germanium halide with coordinating ligands, such as GeCl₂—C₄H₈O₂ (germanium chloride dioxane) is used as the Ge precursor the process temperature can be as low as about 90° C. The vaporization temperature of GeCl₂—C₄H₈O₂ is around 70° C., which can allow deposition temperatures as low as about 90° C.

The skilled artisan can determine the reactant pulse times based on the properties of the selected precursors, the other reaction conditions and the desired properties of the deposited thin film. Preferably the Te and Ge reactant pulses are from about 0.05 to 10 seconds, more preferably the reactant pulses are from about 0.2 to 4 seconds, and most preferably the reactant pulses are from about 1 to 2 seconds in length. The purge steps are preferably about 0.05 to 10 seconds, more preferably about 0.2-4 seconds, and most preferably about 1 to 2 seconds in length.

The growth rate of the GeTe thin film may vary depending on the reaction conditions, including the length of the precursor pulses. As discussed below, in initial experiments a growth rate of around 0.15 Å/cycle was observed on silicon with native oxide with substrate temperatures around 150° C.

The GeTe deposition sub-cycle can be combined with one or more dopant sub-cycles as described herein to form a doped GeTe film.

### Doped GeSbTe Deposition

According to some embodiments, GeₓSb_{y}Te_{z}, preferably Ge₂Sb₂Te₅, (GST) thin films are formed on a substrate by an ALD type process comprising multiple deposition cycles. In particular, a number of Ge—Te and Sb—Te deposition cycles are provided to deposit a GST film with the desired stoichiometry and the desired thickness. The Ge—Te and Sb—Te cycles can be as described above. The skilled artisan will appreciate that multiple Sb—Te deposition cycles can be performed consecutively prior to a Ge—Te cycle, and that multiple Ge—Te deposition cycles can be performed consecutively prior to a subsequent Sb—Te deposition cycle. The particular ratio of cycles can be selected to achieve the desired composition. In some embodiments the GST deposition process begins with a Ge—Te deposition cycle and in other embodiments the GST deposition process begins with an Sb—Te deposition cycle. Similarly, the GST deposition process may end with a Ge—Te deposition cycle or a Sb—Te deposition cycle.

In some preferred embodiments, the Sb—Te and Ge—Te cycles are provided in a 1:1 ratio, meaning they are alternately performed. In other embodiments, the ratio of Sb—Te cycles to the total number of cycles (Ge—Te and Sb—Te cycles combined) is selected such that the compositions of Ge and Sb in the deposited GST thin film are approximately the same. In some embodiments the ratio of Sb—Te cycles to Ge—Te cycles can be between about 100:1 and 1:100.

In some embodiments the method comprises:
providing a first vapor phase reactant pulse comprising a Te precursor into the reaction chamber to form no more than about a single molecular layer of the Te precursor on the substrate;
removing excess first reactant from the reaction chamber;
providing a second vapor phase reactant pulse comprising an Sb precursor to the reaction chamber such that the Sb precursor reacts with the Te precursor on the substrate;
removing excess second reactant and reaction byproducts, if any, from the reaction chamber;
providing a third vapor phase reactant pulse comprising a Te precursor into the reaction chamber to form no more than about a single molecular layer of the Te precursor on the substrate;
removing excess third reactant from the reaction chamber;
providing a fourth vapor phase reactant pulse comprising a Ge precursor to the reaction chamber such that the Ge precursor reacts with the Te precursor on the substrate;
removing excess fourth reactant and reaction byproducts, if any, from the reaction chamber.

The providing and removing steps are repeated until a film of a desired thickness is formed.

The process conditions, precursors, and pulse/purge times are substantially similar to those discussed above.

The GeSbTe deposition sub-cycle can be combined with one or more dopant sub-cycles as described herein to form a doped GeSbTe film.

### Doped GeSbSe Deposition

In other embodiments a GeₓSb_{y}Se_{z}, preferably GeSbSe film, can be formed by using a Se precursor instead of a Te precursor in the process described above for Ge—Sb—Te. The Se precursor preferably has a formula of 2 Se(SiR¹R²R³)₂, wherein R¹, R², and R³ are preferably alkyl groups with one or more carbon atoms. The skilled artisan can choose R¹, R², and R³ alkyl groups based on the desired physical properties of the precursor such as volatility, vapor pressure, toxicity, etc. In some embodiments the Se precursor is Se(SiMe₂^{t}Bu)₂ and in other embodiments is Se(SiEt₃)₂. The ALD process conditions for forming a Ge—Sb—Se thin film are essentially as described above for forming a GST film, with an SbSe deposition cycle substituted for the Sb—Te deposition cycles and a GeSe deposition cycle substituted for the GeTe deposition cycles.

The GeSbSe deposition sub-cycle can be combined with one or more dopant sub-cycles as described herein to form a doped GeSbSe film.

### Doped BiTe Deposition

A BiₓTe_{y}, preferably BiTe, thin film can be formed on a substrate by an ALD type process comprising multiple Bi—Te deposition cycles, each Bi—Te deposition cycle comprising:
providing a first vapor phase reactant pulse comprising a Te precursor into the reaction chamber to form no more than about a single molecular layer of the Te precursor on the substrate;
removing excess first reactant from the reaction chamber;
providing a second vapor phase reactant pulse comprising a Bi precursor to the reaction chamber such that the Bi precursor reacts with the Te precursor on the substrate; and
removing excess second reactant and reaction byproducts, if any, from the reaction chamber.

Each Bi—Te deposition cycle typically forms at most about one monolayer of Bi—Te. The Bi—Te deposition cycle is repeated until a film of a desired thickness is formed. In some embodiments a Bi—Te film of from about 10 Å to about 2000 Å is formed.

Although the illustrated Bi—Te deposition cycle begins with provision of the Te precursor, in other embodiments the deposition cycle begins with the provision of the Bi precursor.

In some embodiments, the reactants and reaction by-products can be removed from the reaction chamber by stopping the flow of Te or Bi precursor while continuing the flow of an inert carrier gas such as nitrogen or argon.

The Te precursor may have a formula of 2 Te(SiR¹R²R³)₂, wherein R¹, R², and R³ are alkyl groups comprising one or more carbon atoms. The R¹, R², and R³ alkyl groups can be selected based on the desired physical properties of the precursor such as volatility, vapor pressure, toxicity, etc. In some embodiments the Te precursor is Te(SiMe₂^{t}Bu)₂. In other embodiments the precursor is Te(SiEt₃)₂.

The Bi precursor may have a formula of BiX₃, wherein X is a halogen element. In some embodiments the Bi precursor is BiCl₃.

The process temperature during the Bi—Te deposition cycle is preferably less than 300° C., and more preferably less than 200° C. The pulse and purge times are typically less than 5 seconds, and preferably around 1-2 seconds. The skilled artisan can choose pulse/purge times based on the particular circumstances.

The BiTe deposition sub-cycle can be combined with one or more dopant sub-cycles as described herein to form a doped BiTe film.

### Doped BiSe Deposition

In other embodiments, a BiₓSe_{y}, preferably BiSe film is formed by using a Se precursor instead of a Te precursor in the ALD process described above for Bi—Te. The Se precursor preferably has a formula of 2 Se(SiR¹R²R³)₂, wherein R¹, R², and R³ are preferably alkyl groups with one or more carbon atoms. The skilled artisan can choose R¹, R², and R³ alkyl groups based on the desired physical properties of the precursor such as volatility, vapor pressure, toxicity, etc. In some embodiments the Se precursor is Se(SiMe₂^{t}Bu)₂ and in other embodiments the Se precursor is Se(SiEt₃)₂. The ALD process conditions for forming a Bi—Se thin film, such as temperature, pulse/purge times, etc. can be selected by the skilled artisan and are essentially as described above for BiTe.

The BiSe deposition sub-cycle can be combined with one or more dopant sub-cycles as described herein to form a doped BiSe film.

### Doped ZnTe Deposition

A ZnₓTe_{y}, such as a ZnTe, thin film, can be formed on a substrate by an ALD type process comprising multiple Zn—Te deposition cycles, each Zn—Te deposition cycle comprising:
providing a first vapor phase reactant pulse comprising a Te precursor into the reaction chamber to form no more than about a single molecular layer of the Te precursor on the substrate;
removing excess first reactant from the reaction chamber;
providing a second vapor phase reactant pulse comprising a Zn precursor to the reaction chamber such that the Zn precursor reacts with the Te precursor on the substrate; and
removing excess second reactant and reaction byproducts, if any, from the reaction chamber.

The ZnTe cycle is repeated until a film of a desired thickness is formed. In some embodiments a ZnTe film of from about 10 Å to about 2000 Å is formed.

Although the illustrated Zn—Te deposition cycle begins with provision of the Te precursor, in other embodiments the deposition cycle begins with the provision of the Zn precursor.

In some embodiments, the reactants and reaction by-products can be removed from the reaction chamber by stopping the flow of Te or Zn precursor while continuing the flow of an inert carrier gas such as nitrogen or argon.

In some embodiments, the Te precursor has a formula of Te(SiR¹R²R³)2, wherein R¹, R², and R³ are preferably alkyl groups with one or more carbon atoms. The skilled artisan can choose R¹, R², and R³ alkyl groups based on the desired physical properties of the precursor such as volatility, vapor pressure, toxicity, etc. In some embodiments the Te precursor is Te(SiMe₂^{t}Bu)₂. In other embodiments the Te precursor is Te(SiEt₃)₂.

In some embodiments, the Zn precursor has a formula of ZnX₂, wherein X is a halogen element or an alkyl group. In some embodiments the Zn precursor is ZnCl₂ or Zn(C₂H₅)₂.

The process temperature during the ZnTe deposition cycle is preferably less than 500° C., and more preferably about 400° C. The pulse and purge times are typically less than 5 seconds, preferably about 0.2-2 seconds, and more preferably about 0.2-1 seconds. The skilled artisan can choose appropriate pulse/purge times based on the particular circumstances.

The ZnTe deposition sub-cycle can be combined with one or more dopant sub-cycles as described herein to form a doped ZnTe film.

### Doped ZnSe Deposition

In other embodiments a ZnₓSe_{y}, preferably ZnSe, film can be formed by using a Se precursor in place of a Te precursor in the deposition cycle outlined above. The Se precursor preferably has a formula of 2 Se(SiR¹R²R³)₂, wherein R¹, R², and R³ are preferably alkyl groups with one or more carbon atoms. The skilled artisan can choose R¹, R², and R³ alkyl groups based on the desired physical properties of the precursor such as volatility, vapor pressure, toxicity, etc. In some embodiments the Se precursor is Se(SiMe₂^{t}Bu)₂ and in other embodiments is Se(SiEt₃)₂. The ALD process conditions for forming a Zn—Se thin film, such as temperature, pulse/purge times, etc. can be selected by the skilled artisan and are essentially as described above for deposition of Zn—Te.

The ZnSe deposition sub-cycle can be combined with one or more dopant sub-cycles as described herein to form a doped ZnSe film.

It will be appreciated by those skilled in the art that various modifications and changes can be made without departing from the scope of the invention. Similar other modifications and changes are intended to fall within the scope of the invention, as defined by the appended claims.

We claim:

1. An atomic layer deposition (ALD) method for forming a selector device comprising depositing a doped chalcogenide film on a substrate by a process comprising multiple deposition cycles in which the substrate is alternately and sequentially contacted with two or more reactants for forming the chalcogenide film, and wherein the substrate is contacted with a third dopant precursor in one or more of the deposition cycles.

2. The method of claim 1, wherein the substrate is alternately and sequentially contacted with each of the reactants in the one or more of the deposition cycles.

3. The method of claim 1, wherein the ALD method comprises two or more deposition cycles in which the substrate is alternately and sequentially contacted with the first reactant, the second reactant and the dopant precursor to form the doped chalcogenide film.

4. The method of claim 1, wherein the ALD method comprises a first primary deposition sub-cycle in which the substrate is alternately and sequentially contacted with the first reactant and a second reactant to form a chalcogenide material and a second dopant sub-cycle in which the substrate is contacted with the dopant precursor.

5. The method of claim 4, wherein the substrate is alternately and sequentially contacted with one or both of the first and second reactants and the dopant precursor in the dopant sub-cycle.

6. The method of claim 4, wherein the dopant sub-cycle is provided at one or more intervals in the ALD method to obtain the desired dopant content in the doped chalcogenide film.

7. The method of claim 4, wherein the dopant precursor comprises a halide precursor or an alkylsilyl precursor.

8. The method of claim 1, wherein the first reactant is an alkyl silyl precursor and the second reactant is a metal halide precursor.

9. The method of claim 1, wherein the doped chalcogenide film is a doped GeSe film.

10. The method of claim 9, wherein the doped GeSe film is deposited using a Ge halide first reactant and a Se alkyly silyl second reactant.

11. The method of claim 10, wherein the first reactant is GeCl₂—C₄H₈O₂ and the second reactant is (Et₃Si)Se₂.

12. The method of claim 1, wherein the dopant precursor comprises one or more dopants selected from C, Sb, As, Si, S, N, Ti, Sn, Ta, W, Mo, Al, Zn, In, Ga, Bi, Sb, As, V and B.

13. The method of claim 1, wherein the doped chalcogenide film is doped with carbon using a carbon dopant precursor.

14. The method of claim 13, wherein the carbon dopant precursors contains Cl and C.

15. The method of claim 14, wherein the carbon dopant precursor is CCl₄.

16. The method of claim 14, wherein the carbon dopant precursor has the formula CₓH_{y}Cl_{z}, wherein x, y and z are integers.

17. The method of claim 16, wherein the carbon dopant precursor is CH₃Cl or CH₂Cl₂.

18. The method of claim 1, wherein the doped chalcogenide film is doped with As using an As dopant precursor.

19. The method of claim 18, wherein the As dopant precursor is an alkyl silyl As precursor.

20. The method of claim 19, wherein the As dopant precursor is (Et₃Si)₃As.

21. The method of claim 1, wherein the doped chalcogenide film is doped with Sb using an Sb dopant precursor.

22. The method of claim 21, wherein the Sb dopant precursor is an alkyl silyl precursor.

23. The method of claim 22, wherein the Sb dopant precursor is (Me₃Si)₃Sb.

24. The method of claim 1, wherein the doped chalcogenide film is doped with a metal selected from Ti, Sn, Ta, W, Mo, Al, Zn, In, Ga, Bi, Sb, As, V or B.

25. The method of claim 24, wherein the dopant precursor is a metal halide precursor selected from TiCl₄, SnCl₄, TaCl₅, WCl₆, MoCl₅, AlCl₃, ZnClₓ, InClₓ, GaClₓ, BiClₓ, SbClₓ, AsClₓ, VClₓ, BCl₃, and BBrₓ.

26. The method of claim 1, wherein the dopant precursor is TiCl₄, SnCl₄, or GaCl₃.

27. The method of claim 1, wherein the metal dopant precursor is a metal alkylsilyl compound.

28. The method of claim 1, wherein the doped chalcogenide film is doped with nitrogen using a nitrogen dopant precursor.

29. The method of claim 28, wherein the dopant precursor comprises NH₃.

30. The method of claim 29, wherein the first reactant is GeClₓ and the second reactant is alkylsilyl selenium and a nitrogen doped GeSe film is formed.

31. The method of claim 1, wherein the doped chalcogenide film is doped with sulfur using a sulfur dopant precursor.

32. The method of claim 31, wherein the sulfur dopant precursor comprises an alkyl silyl sulfur compound.

33. The method of claim 1, wherein a first Ge precursor is used as the first reactant and a second, different Ge precursor is used as the dopant precursor.

34. The method of claim 33, wherein GeCl₂X and GeCl₄ are used as the first reactant and the dopant precursor, where X is an organic ligand.

35. The method of claim 34, wherein the film is doped with carbon.

36. The method of claim 33, wherein germanium alkylsilyl is used as the first or second Ge precursor.

37. The method of claim 1, wherein an (Sb) metal chloride and/or Sb(OEt)3 is used in combination with one or more alkyl silyl precursors.

38. The method of claim 1, wherein the dopant precursor is an alkoxide precursors.

39. The method of claim 38, wherein the alkoxide precursor is Si(OEt)₄ (TEOS).

40. The method of claim 1, wherein the dopant precursor is BTBAS ((1,2-bis(diisopropylamino)disilane)).

41. The method of claim 1, wherein the dopant precursor is an organic precursor that provides carbon as a dopant.

42. The method of claim 1, wherein the doped chalcogenide film is a phase change material in the selector device.

43. The method of claim 1, wherein the doped chalcogenide film comprises one or more of GeSe, Sb—Te, Ge—Te, Ge—Sb—Te, Bi—Te, Zn—Se, or Zn—Te.

44. The method of claim 1, wherein the dopant precursor is a plasma reactant.

45. The method of claim 47, wherein the plasma reactant provides O, N or Si as a dopant.

46. A process for depositing a doped chalcogenide film on a substrate, the process comprising a plurality of complete deposition cycles, each complete deposition cycle comprising a chalcogenide sub-cycle and a dopant sub-cycle,
wherein the chalcogenide sub-cycle comprises alternately and sequentially contacting the substrate with a metal precursor and a chalcogenide precursor; and
wherein the dopant sub-cycle contacting the substrate with a first dopant precursor, and
wherein the doped chalcogenide film is a phase change material.

47. The process of claim 46, wherein the doped chalcogenide film is part of a selector device.

48. The process of claim 46, wherein the dopant sub-cycle comprises alternately and sequentially contacting the substrate with the first dopant precursor and a second reactant.

49. The process of claim 46, wherein the second reactant comprises the same chalcogenide precursor as the chalcogenide precursor in the chalcogenide sub-cycle.

50. The process of claim 46, wherein the metal precursor is a metal halide and the chalcogenide precursor is an alkyl silyl compound.

51. The process of claim 46, wherein the doped chalcogenide film comprises one or more of GeSe, SbTe, GeTe, GeSbTe, BiTe, ZnSe, and ZnTe.

52. The process of claim 46, wherein the doped chalcogenide film is doped with one or more of C, Sb, As, Si, S, N, Ti, Sn, Ta, W, Mo, Al, Zn, In, Ga, Bi, Sb, As, V and B.

53. The process of claim 46, wherein the chalcogenide sub-cycle and the dopant sub-cycle comprise an atomic layer deposition (ALD) processes.
